(19) United States
(12) Patent Application Publication
(10) Pub. No.: US 2022/0122781 A1
(43) Pub. Date: Apr. 21, 2022

(54) PHOTOVOLTAIC DEVICES COMPRISING LUMINESCENT SOLAR CONCENTRATORS AND PEROVSKITE-BASED PHOTOVOLTAIC CELLS

(71) Applicant: ENI S.P.A., Roma (IT)

(72) Inventors: Roberto Fusco, Novara (IT); Gabriella Tozzola, Novara (IT)

(73) Assignee: ENI S.P.A., Munich (DE)

(21) Appl. No.: 17/268,988

(22) PCT Filed: Aug. 14, 2019
(86) PCT No.: PCT/IB2019/056892

§ 371 Date: Feb. 17, 2021

(30) Foreign Application Priority Data
Aug. 17, 2018 (IT) 102018000008110

(51) Int. Cl. H01G 9/20; H01L 51/42; H01L 51/44; H01L 51/00

(52) U.S. Cl. CPC H01G 9/209; H01G 9/2009; H01L 51/0077; H01L 51/447; H01L 51/4253

(57) ABSTRACT

A photovoltaic device or solar device including at least one luminescent solar concentrator (LSC) having an upper surface, a lower surface and one or more external sides; at least one perovskite-based photovoltaic cell or solar cell positioned on the outside of at least one of the external sides of said luminescent solar concentrator (LSC), the perovskite being selected from organometal trihalides. The photovoltaic device or solar device may be used advantageously in various applications necessitating the production of electrical energy by utilising light energy, in particular solar radiation energy such as, for example: building integrated photovoltaic (BIPV) systems, photovoltaic windows, greenhouses, photobioreactors, noise barriers, lighting equipment, design, advertising, automotive industry. Moreover, the photovoltaic device or solar device can be used both in stand-alone mode and in modular systems.

This application claims priority under 35 U.S.C. § 119(a) to Italian Patent Application No. 102018000008110 filed on Aug. 17, 2018 and is a national phase application under 35 U.S.C. § 371, of International Patent Application No. PCT/162019/056892 filed on Aug. 14, 2019 the contents of which are incorporated by reference herein in their entirety.

### BACKGROUND OF THE DISCLOSURE

### 1. Field of the Disclosure

The present invention relates to photovoltaic devices (or solar devices) comprising luminescent solar concentrators (LSCs) and perovskite-based photovoltaic cells (or solar cells).

More particularly, the present invention relates to a photovoltaic device (or solar device) comprising: at least one luminescent solar concentrator (LSC) having an upper surface, a lower surface and one or more external sides; at least one perovskite-based photovoltaic cell (or solar cell) positioned on the outside of at least one of the external sides of said luminescent solar concentrator (LSC), said perovskite being selected from organometal trihalides.

Said photovoltaic device (or solar device) may be used advantageously in various applications necessitating the production of electrical energy by utilising light energy, in particular solar radiation energy such as, for example: building integrated photovoltaic (BIPV) systems, photovoltaic windows, greenhouses, photobioreactors, noise barriers, lighting equipment, design, advertising, automotive industry. Moreover, said photovoltaic device (or solar device) can be used both in stand-alone mode and in modular systems.

### 2. Description of the Related Art

Typically, the luminescent solar concentrators (LSCs) known in the art are in the form of a plate comprising a matrix of a transparent material which, as such, is transparent to the radiation of interest (for example, transparent glass panes or transparent polymeric materials), and one or more photoluminescent compounds generally selected, for example, from organic compounds, metal complexes, inorganic compounds (for example, rare earths), quantum dots (QDs). Due to the effect of the optical phenomenon of total reflection, the radiation emitted by the photoluminescent compounds is “guided” towards the thin external sides of said plate, where it is concentrated on photovoltaic cells (or solar cells) positioned there. In this way, large surfaces of low-cost materials (said plate) can be used to concentrate the light onto small surfaces of high-cost materials [photovoltaic cells (or solar cells)]. Said photoluminescent compounds can be deposited on the matrix of transparent material in the form of a thin film, or they can be dispersed within the transparent matrix. Alternatively, they can be dispersed within the transparent matrix. Alternatively, the transparent matrix can be directly functionalised with photoluminescent chromophore groups.

At the state of the art, the performances of luminescent solar concentrators (LSCs) depends on various factors, the most relevant being, for example, both the efficiency of conversion of the photoluminescent compounds used that absorb photons at lower wavelengths and convert them into photons of greater wavelength, and the efficiency of the photovoltaic cells (or solar cells) positioned on the external sides of the plate, which convert the latter into electrical energy. The more able the photovoltaic cells (or solar cells) are to utilise the energy of the photons emitted by the photoluminescent compounds in the conversion into electrical energy, the greater will be the efficiency of the photovoltaic device (or solar device).

At the present time, the photovoltaic cells (or solar cells) most often used together with luminescent solar concentrators (LSCs) are the inorganic ones, in particular, photovoltaic cells (or solar cells) based on crystalline silicon which, in conditions of direct solar irradiation, give the best performance/production cost ratio.

However, because photovoltaic cells (or solar cells) based on crystalline silicon generally have both low band-gap values (i.e. low values for the energy difference between the conduction band and the valency band) (for example, band-gap values ranging from about 1.0 eV to about 1.1 eV) and low values for the open-circuit voltage (Voc) [for example, values for the open-circuit voltage (Voc) ranging from about 0.5 V to 0.6 V], said photovoltaic cells (or solar cells) based on crystalline silicon do not permit the best use of the radiation emitted by the luminescent solar concentrators (LSCs) (generally ranging from 1.5 eV to 2.0 eV).

The coupling of luminescent solar concentrators (LSCs) with photovoltaic cells (or solar cells) different from those based on crystalline silicon, has been described in the literature.

For example, it is known the coupling of luminescent solar concentrators (LSCs) with inorganic solar cells based on gallium arsenide (GaAs) or gallium and indium phosphide (InGaP) as reported, for example, by Debjie M. G. et al., in “Advanced Energy Materials” (2012), Vol. 2, pag. 12-35.

Koeppe R. et al., in “Applied Physics Letters” (2007), Vol. 90, 181126, report the coupling of luminescent solar concentrators (LSCs) with organic solar cells based on zinc phthalocyanine and fullerene C₆₀.

McKenna B. et al., in “Advanced Materials” (2017), 1606491, report the use of luminescent solar concentrators (LSCs) with various types of solar cells such as, for example, solar cells based on crystalline silicon, solar cells based on gallium arsenide (GaAs), perovskite-based solar cells, organic solar cells, dye-sensitised solar cells (DSSCs). In particular, perovskite-based solar cells are reported, the surface of which is coated with a layer of luminescent material for the purpose of improving their stability to ultraviolet radiation.

Chander N. et al., in “Applied Physics Letters” (2014), Vol. 105, 33904, report a simple method for improving stability to ultraviolet radiation in perovskite-based solar cells using a transparent layer of luminescent material based on a phosphorus of nanometric dimensions (nano-phosphor), i.e. based on YVO₄:Eu³⁺ obtained by hydrothermal treatment, as coating. The above-mentioned layer is also said to allow an improvement in the efficiency of said perovskite-based solar cells in terms of power conversion efficiency (PCE).

Hou X. et al., in “Solar Energy Materials & Solar Cells” (2016), Vol. 149, pag. 121-127, report high-performance perovskite-based solar cells in which a phosphorus of nanometric dimensions (nanophosphor) is incorporated in the mesoporous layer of titanium dioxide, i.e. ZnGa₂O₄:Eu³⁺. The above-mentioned perovskite-based solar cells are said to show an improvement both in terms of power conversion efficiency (PCE) and in terms of short-circuit photocurrent density (Jsc).

Bella F. et al., in “Science” (2016), Vol. 354(6309), pag. 203-206, report perovskite-based solar cells having improved performances and stability to ultraviolet radiation and water, thanks to a coating based on fluorinated photopolymers.

U.S. Pat. No. 8,952,239 relates to a solar module comprising various solar concentrators. In one embodiment, a solar module includes a series of photovoltaic cells and a solar concentrator coupled to said series of photovoltaic cells. Said photovoltaic cells may be crystalline silicon-based or based on amorphous silicon, germanium, inorganic materials or semiconductor materials of groups III-V, such as gallium arsenide.

U.S. patent application 2014/0283896 relates to a transparent luminescent solar concentrator (LSC). In particular, said luminescent solar concentrator (LSC) has luminophores incorporated in a waveguide matrix which selectively absorbs and emits light in the near infrared to a photovoltaic array mounted on the edge of said luminescent solar concentrator (LSC) or incorporated in said luminescent solar concentrator (LSC). Said photovoltaic array may also comprise perovskite-based solar cells.

International patent application WO 2015/079094 relates to a solar concentrator characterised in that it comprises: a transparent or semi-transparent substrate; a coating of photonic crystals; at least one photovoltaic cell placed on said substrate, the active surface of said at least one photovoltaic cell being placed in parallel to said substrate; and a layer of luminescent material placed in contact with said coating of photonic crystals, wherein said coating of photonic crystals is placed on said substrate and the layer of luminescent material is placed on said coating of photonic crystals; or said layer of luminescent material is placed on said substrate and the coating of photonic crystals is placed on said layer of luminescent material. Perovskite-based solar cells are also cited among the photovoltaic cells that can be used for this purpose.

However, from the prior art mentioned above, it can be seen that the coupling of luminescent solar concentrators (LSCs) with perovskite-based photovoltaic cells (or solar cells) is not specifically described and/or exemplified.

Perovskite-based photovoltaic cells (or solar cells) are relatively new entrants into solar photovoltaic technologies and have witnessed a very great improvement in power conversion efficiency within a very short time. In particular, in only five years, from 2012 to 2016, perovskite-based photovoltaic cells (or solar cells) have passed from a power conversion efficiency of around 4% up to 22.1% as demonstrated on the following Internet site: https://www.nrel.gov/pv/assets/images/efficiency-chart.png. The type of perovskite-based photovoltaic cells (or solar cells) widely used in the photovoltaics (or solar energy) field is the hybrid organic-inorganic one based on an organometal halide material characterised by high extinction coefficients and charge mobility. The perovskite structure is generally represented by the formula ABX₃ and, in the case of said organometal halide material, A represents an organic cation, B represents a metal cation, and X represents a halogen anion. In particular, the type of perovskite most often used currently is that based on lead halides, wherein A (the organic cation) is methylammonium CH₃NH₃⁺, B (the metal cation) is the lead ion Pb²⁺ and X (the halogen anion) is the tri-iodide ion I⁻, so that the overall formula is CH₃NH₃PbI₃. The bandgap of said type of perovskite is equal to 1.57 eV, corresponding to a wavelength of about 790 nm and therefore succeeding in absorbing the whole of the visible spectrum.

Moreover, perovskite-based photovoltaic cells (or solar cells) are easy to produce and use common materials and are therefore also advantageous economically. More specifically, said perovskite-based photovoltaic cells (or solar cells) combine crystallinity and high charge transfer [both of electrons (−) and of electron gaps (or holes) (+)] found in inorganic semiconductors, with the low-cost production of photovoltaic cells (or solar cells) based on low-temperature processes in the presence of solvent. Furthermore, unlike conventional semiconductor photovoltaic cells (or solar cells), perovskite-based photovoltaic cells (or solar cells) are able, by varying the type of atoms in their crystalline structure, to emulate the bandgap, and therefore the capacity to absorb in particular portions of the solar spectrum. On the other hand, said perovskite-based photovoltaic cells (or solar cells) exhibit an external quantum efficiency (EQE) that is lower than the external quantum efficiency (EQE) of photovoltaic cells (or solar cells) based on crystalline silicon.

Further details about perovskite-based photovoltaic cells (or solar cells) may be found, for example, in: Cui J. et al., “Science and Technology of Advanced Materials” (2015), Vol. 16, 036004; Eperon G. E. et al., “Energy & Environmental Science” (2014), Vol. 7, pag. 982-988; Li G. et al., “Advanced Energy Materials” (2015), 1401775.

The study of photovoltaic devices (or solar devices) comprising luminescent solar concentrators (LSCs) and perovskite-based photovoltaic cells (or solar cells) is therefore of great interest.

The Applicant therefore posed the problem of discovering a photovoltaic device (or solar device) comprising luminescent solar concentrators (LSCs) and perovskite-based photovoltaic cell cells (or solar cells) that are capable of exhibiting good values of electrical power density (□) and, consequently, good performances.

### SUMMARY

The Applicant has now discovered a perovskite-based photovoltaic cell (or solar cell) comprising at least one luminescent solar concentrator (LSC) and at least one perovskite-based photovoltaic cell (or solar cell) that are capable of exhibiting good values of electrical power density (□) and, consequently, good performances. Furthermore, said photovoltaic device (or solar device) exhibits a ratio between the electrical power density (□) generated and the electrical power density expected (expected), calculated as reported below, greater than 1 and, consequently, a greater generated electrical power density (□) with respect to that expected. Said photovoltaic device (or solar device) may be used advantageously in various applications necessitating the production of electrical energy by utilising light energy, in particular solar radiation energy such as, for example: building integrated photovoltaic (BIPV) systems, photovoltaic windows, greenhouses, photobioreactors, noise barriers, lighting equipment, design, advertising, automotive industry. Moreover, said photovoltaic device (or solar device) can be used both in stand-alone mode and in modular systems.

The object of the present invention is therefore a photovoltaic device (or solar device) comprising:
at least one luminescent solar concentrator (LSC) having an upper surface, a lower surface and one or more external sides;
at least one perovskite-based photovoltaic cell (or solar cell) positioned outside of at least one of the external sides of said luminescent solar concentrator (LSC), said perovskite being selected from organometal trihalides.

For the purpose of the present description and of the claims which follow, unless otherwise specified the definitions of the numerical ranges always comprise the extremes.

For the purpose of the present description and of the claims which follow, the term “comprising” also includes the terms “that consists essentially of” or “that consists of”.

As mentioned above, said luminescent solar concentrator (LSC) has an upper surface, a lower surface and one or more external sides. According to one embodiment, said luminescent solar concentrator (LSC) may have one external side (e.g., it may be circular), three, four, five, six, seven, or more sides. According to one embodiment, said luminescent solar concentrator (LSC) may have a lower surface distanced from the upper surface, wherein the external side(s) extends/extend from the upper surface to the lower one. According to one embodiment, said upper surface is configured to receive photons from a photon source and is positioned closer to the photon source with respect to said lower surface.

According to a preferred embodiment of the present invention, said luminescent solar concentrator (LSC) has an upper surface configured to receive the photons, a lower surface configured to receive the photons, said upper surface being positioned closer to the photon source with respect to the lower surface, and four external sides that extend from the upper surface to the lower one.

According to a preferred embodiment of the present invention, said luminescent solar concentrator (LSC) is a plate comprising a matrix in transparent material and at least one photoluminescent compound.

According to a preferred embodiment of the present invention, said transparent material may be selected, for example, from: transparent polymers such as, for example, polymethyl methacrylate (PMMA), polycarbonate (PC), polyisobutyl methacrylate, polyethyl methacrylate, polyallyl diglycol carbonate, polymethacrylimide, polycarbonate ether, polyethylene terephthalate, polyvinyl butyral, ethylene-vinylacetate copolymers, ethylene-tetrafluoroethylene copolymers, polyimide, polyurethane, styrene-acrylonitrile copolymers, styrene-butadiene copolymers, polystyrene, methyl-methacrylate styrene copolymers, polyethersulfone, polysulfone, cellulose triacetate, transparent and impact-resistant crosslinked acrylic compositions consisting of a fragile matrix (I) having a glass transition temperature (T_{g}) above 0° C. and elastomeric domains having dimensions smaller than 100 nm which consist of macromolecular sequences (II) having a flexible nature with a glass transition temperature (T_{g}) below 0° C. and described, for example, in U.S. patent application 2015/0038650 (hereinafter referred to, for greater simplicity, as PPMA-HR), or mixtures thereof; transparent glass such as, for example, silica, quartz, alumina, titanium dioxide, or mixtures thereof. Polymethylmethacrylate (PMMA), PMMA-IR, or mixtures thereof, are preferred. Preferably, said transparent material may have a refractive index ranging from 1.30 to 1.70.

According to a preferred embodiment of the present invention, said photoluminescent compound may be selected, for example, from: perylene compounds such as, for example, compounds known with the commercial name of Lumogen® from BASF; acene compounds described, for example, in international patent application WO 2011/048458 in the name of the Applicant; benzothiadiazole compounds described, for example, in international patent application WO 2011/048458 in the name of the Applicant; compounds comprising a benzoheterodiazole group and at least one benzodithiophene group described, for example, in international patent application WO 2013/098726 in the name of the Applicant; disubstituted naphtathiadiazole compounds described, for example, in European patent application EP 2 789 620 in the name of the Applicant; benzoheterodiazole compounds disubstituted with benzodithiophene groups described, for example, in European patent application EP 2 789 620 in the name of the Applicant; disubstituted benzoheterodiazole compounds described, for example, in international patent application WO 2016/046310 in the name of the Applicant; disubstituted diaryloxybenzoheterodiazole compounds described, for example, in international patent application WO 2016/046319 in the name of the Applicant; or mixtures thereof.

Specific examples of photoluminescent compounds that may advantageously be used for the purpose of the present invention are: N,N′-bis(2′,6′-di-iso-propylphenyl)(1,6,7,12-tetraphenoxy)(3,4,9,10-perylene diimide (Lumogen® F Red 305—Basf), 9,10-diphenylanthracene (DPA), 4,7-di(thien-2′-yl)-2,1,3-benzothiadiazole (DTB), 5,6-diphenoxy-4,7-bis(2-thienyl)-2,1,3-benzothiadiazole (DTBOP), 5,6-diphenoxy-4,7-bis[5-(2,6-dimethylphenyl)-2-thienyl]benzo[c]1,2,5-thiadiazole (MPDTBOP), 5,6-diphenoxy-4,7-bis[5-(2,5-dimethylphenyl)-2-thienyl]benzo[c]1,2,5-thiadiazole (PPDTBOP), 4,7-bis[5-(2,6-dimethylphenyl)-2-thienyl]benzo[c]1,2,5-thiadiazole (MPDTB), 4,7-bis[5-(2,6-di-iso-propylphenyl)-2-thienyl]benzo[c]1,2,5-thiadiazole (IPPDTB), 4,7-bis[4,5-(2,6-dimethylphenyl)-2-thienyl]benzo[c]1,2,5-thiadiazole (2MPDTB) [1,2,5]thiadiazole (F500), 4,9-bis(7′,8′-dibutylbenzo[1′,2′-b′:4′,3′-b″]dithien-5′-yl)-naphtho[2,3-c][1,2,5]thiadiazole (F521), 4,7-bis(5-(thiophen-2-yl)thiophen-2-yl)benzo[c][1,2,5]thiadiazole (QTB), 4,9-bis(thien-2′-yl)-naphtho[2,3-c][1,2,5]thiadiazole (DTN), or mixtures thereof. 9,10-5,6-Diphenoxy-4,7-bis[5-(2,6-dimethylphenyl)-2-thienyl]benzo[c]1,2,5-thiadiazole (MPDTBOP), 5,6-diphenoxy-4,7-bis[5-(2,5-dimethylphenyl)-2-thienyl]benzo[c]1,2,5-thiadiazole (PPDTBOP), N,N′-bis(2′,6′-di-iso-propylphenyl)(1,6,7,12-tetraphenoxy)(3,4,9,10-perylene diimide (Lumogen® F. Red 305—Basf), or mixtures thereof, are preferred.

According to a preferred embodiment of the present invention, said photoluminescent compound may be present in said transparent matrix in a quantity ranging from 0.1 g per unit of surface area to 3 g per unit of surface area, preferably ranging from 0.2 g per unit of surface area to 2.5 g per unit of surface area, said unit of surface area being referred to the surface area of the matrix in transparent material expressed in m².

According to a further embodiment of the present invention, said photoluminescent compound may be selected, for example, from quantum dots (QDs), which may be composed of different elements that may be selected, for example, from the elements belonging to groups 12-16, 13-15, 14-16, of the Periodic Table of the Elements. Preferably, said quantum dots (QDs) may be selected, for example from: lead sulphide (PbS), zinc sulphide (ZnS), cadmium sulphide (CdS), cadmium selenide (CdSe), cadmium telluride (CdTe), silver (Ag), gold (Au), aluminium (Al), or mixtures thereof.

For the purpose of the present description and of the claims which follow, the term “Periodic Table of the Elements” refers to the “IUPAC Periodic Table of the Elements”, version dated 8 Jan. 2016, reported on the following Internet site: https://iupac.org/what-we-do/periodic-table-of-elements/.

Further information relating to said quantum dots (QDs) may be found, for example, in U.S. patent application 2011/240960.

According to a preferred embodiment of the present invention, said photoluminescent compound, when selected from said quantum dots (QDs), may be present in said transparent matrix in a quantity ranging from 0.05 g per unit of surface area to 100 g per unit of surface area, preferably ranging from 0.15 g per unit of surface area to 20 g per unit of surface area, said unit of surface area being referred to the surface area of the matrix in transparent material expressed in m².

According to a preferred embodiment of the present invention, said luminescent solar concentrator (LSC) is a plate having a thickness ranging from 0.1 μm to 50 mm, preferably ranging from 0.5 μm to 20 mm.

The above-mentioned photoluminescent compounds may be used in said luminescent solar concentrator (LSC), in various forms.

For example, in the case wherein the transparent matrix is of the polymeric type, said at least one photoluminescent compound may be dispersed in the polymer of said transparent matrix by, for example, melt dispersion, or addition in bulk, and subsequent formation of a plate comprising said polymer and said at least one photoluminescent compound, working, for example, in accordance with the casting technique. Alternatively, said at least one photoluminescent compound and the polymer of said transparent matrix may be solubilised in at least one suitable solvent, obtaining a solution that is deposited on a plate of said polymer, forming a film comprising said at least one photoluminescent compound and said polymer, working, for example, by the use of a Doctor Blade-type film applicator: said solvent is then allowed to evaporate. Said solvent may be selected, for example, from: hydrocarbons such as, for example, 1,2-dichloromethane, 1,2-dichlorobenzene, toluene, hexane; ketones such as, for example, acetone, acetylacetone; or mixtures thereof.

In the case wherein the transparent matrix is of the vitreous type, said at least one photoluminescent compound may be solubilised in at least one suitable solvent (that can be selected from among those mentioned above), obtaining a solution that is deposited on a plate of said transparent matrix of vitreous type, forming a film comprising said at least one photoluminescent compound working, for example, by the use of a Doctor Blade-type film applicator: said solvent is then allowed to evaporate.

Alternatively, a plate comprising said at least one organic photoluminescent compound and said polymer, obtained as described above according to the casting technique, may be enclosed between two plates of said transparent matrix of the vitreous type (sandwich) working according to the known technique used to prepare double-glazed units in an inert atmosphere.

For the purpose of the present invention, said luminescent solar concentrator (LSC) may be produced in plate form by addition in bulk and subsequent casting, as described above: further details may be found in the examples which follow.

In accordance with a preferred embodiment of the present invention, said perovskite may be selected, for example, from organometal trihalides having general formula ABX₃, wherein:
A represents an organic cation such as, for example, methylammonium (CH₃NH₃⁺), formamidinium [CH(NH₂)₂⁺], n-butylammonium (C₄H₁₂N⁺), tetra-butylammonium (C₁₆H₃₆N⁺);
B represents a metallic cation such as, for example, lead (Pb²⁺), tin (Sn²⁺);
X represents a halogen ion such as, for example, iodine (I⁻), chlorine (Cl⁻), bromine (Br⁻).

In accordance with a further preferred embodiment of the present invention, said perovskite may be selected, for example from: methyl ammonium lead iodide (CH₃NH₃PbI₃), methyl ammonium lead bromide (CH₃NH₃PbBr₃), methyl ammonium lead chloride (CH₃NH₃PbCl₃), methyl ammonium lead iodide bromide (CH₃NH₃PbIₓBr₃₋ₓ), methyl ammonium lead iodide chloride (CH₃NH₃PbIₓCl₃₋ₓ), formamidinium lead iodide [CH(NH₂)₂PbI₃], formamidinium lead bromide [CH(NH₂)₂PbBr₃], formamidinium lead chloride [CH(NH₂)₂PbCl₃], formamidinium lead iodide bromide [CH(NH₂)₂PbIₓBr₃₋ₓ], formamidinium lead iodide chloride [CH(NH₂)₂PbIₓCl₃₋ₓ], n-butyl ammonium lead iodide (C₄H₁₂NPbI₃), tetra-butyl ammonium lead iodide (C₁₆H₃₆NPbI₃), n-butyl ammonium lead bromide (C₄H₁₂NPbBr₃), tetra-butyl ammonium lead bromide (C₁₆H₃₆NPbBr₃), methyl ammonium tin iodide (CH₃NH₃SnI₃), methyl ammonium tin bromide (CH₃NH₃SnBr₃), methyl ammonium tin iodide bromide (CH₃NH₃SnIₓBr₃₋ₓ), formamidinium tin iodide [CH(NH₂)₂SnI₃], formamidinium tin iodide bromide [CH(NH₂)₂SnIₓBr₃₋ₓ], n-butyl ammonium tin iodide (C₄H₁₂NSnI₃), tetra-butyl ammonium tin iodide (C₁₆H₃₆NSnI₃), n-butyl ammonium tin bromide (C₄H₁₂NSnBr₃), tetra-butyl ammonium tin bromide (C₁₆H₃₆NSnBr₃), methyl ammonium tin iodide (CH₃NH₃SnI₃), or mixtures thereof. Methyl ammonium lead iodide (CH₃NH₃PbI₃) is preferred.

For the purpose of the present invention, said perovskite-based photovoltaic cell (or solar cell) may be selected from the perovskite-based photovoltaic cells (or solar cells) of the prior art.

For the purpose of the present invention, said perovskite-based photovoltaic cell (or solar cell) comprises:
a substrate of glass coated with a layer of transparent and conductive oxide (TCO), commonly tin oxide doped with fluorine (SnO₂:F) (Fluorinated Tin Oxide—FTO), or indium oxide doped with tin (Indium Tin Oxide—ITO) constituting the anode;
an electron transporter layer (Electron Transport Material—ETO) the purpose of which is to extract the electrons photogenerated by the perovskite and transfer them to the anode; this is also called a “blocking layer” in that it blocks the electron gaps (or holes) and, generally, is a compact layer of titanium dioxide (TiO₂);
optionally, a scaffold of mesoporous titanium dioxide (TiO₂) the purpose of which is to provide a larger area of interface with the perovskite, increasing the efficiency of harvesting of electrons, which must follow a shorter course, seeing the probability of recombination reduced; it can also lengthen the optical path, favouring the absorption of radiation;
a layer of perovskite, preferably of methyl ammonium lead iodide (CH₃NH₃PbI₃), which is the absorbent layer, methyl ammonium lead iodide (CH₃NH₃PbI₃), as mentioned above, is the structure most often used, because it exhibits a high coefficient of absorption over the whole UV and visible spectrum, a bandgap of 1.57 eV, close to the optimum value for maximising the conversion efficiency and a considerable distance for diffusion of the electrons and electron gaps (or holes) (more than 100 nm);
a layer based on a hole transport material (HTM), generally of spiro-MeOTAD [2,2′,7,7′-tetrakis(N,N-di-4-methoxyphenylamine)-9,9′-spirobifluorene];
a metallic contact known as a “back contact”, which constitutes the cathode, generally a layer of gold or silver.

Said perovskite-based photovoltaic cell (or solar cell) may be constructed by working according to processes known in the art, as described, for example, by Li G. et al., in Advanced Energy Materials (2015), 1401775, mentioned above: further details relating to the construction of said perovskite-based photovoltaic cell (or solar cell) can be found in the examples which follow.

For the purpose of improving adhesion between said at least one luminescent solar concentrator (LSC) and said at least one perovskite-based photovoltaic cell (or solar cell), a suitable optical gel may be used.

According to a preferred embodiment of the present invention, said at least one perovskite-based photovoltaic cell (or solar cell) may be coupled to at least one of the external sides of said luminescent solar concentrator (LSC) with use of a suitable optical gel. Said optical gel must have a refraction index that allows good optical coupling and may be selected, for example, from transparent silicone oils and fats, epoxy resins.

According to a preferred embodiment of the present invention, the electrical energy generated by said at least one perovskite-based photovoltaic cell (or solar cell) may be transported using a wiring system that is connected to said photovoltaic device (or solar device).

For the purpose of the present invention, one or more perovskite-based photovoltaic cells (or solar cells) may be positioned outside of at least one of the sides of said luminescent solar concentrator (LSC), preferably said perovskite-based photovoltaic cells (or solar cells) may partially or completely cover the outer perimeter of said luminescent solar concentrator (LSC).

For the purpose of the present description and the claims which follow, the term “outer perimeter” is intended to mean the external sides of said luminescent solar concentrator (LSC).

As mentioned above, said photovoltaic device (or solar device) may be used advantageously in various applications necessitating the production of electrical energy by utilising light energy, in particular solar radiation energy such as, for example: building integrated photovoltaic (BIPV) systems, photovoltaic windows, greenhouses, photobioreactors, noise barriers, lighting equipment, design, advertising, automotive industry. Moreover, said photovoltaic device (or solar device) can be used both in stand-alone mode and in modular systems.

A further subject of the present invention is therefore the use of said photovoltaic device (or solar device) in: building integrated photovoltaic (BIPV) systems, photovoltaic windows, greenhouses, photobioreactors, noise barriers, lighting equipment, design, advertising, automotive industry.

### BRIEF DESCRIPTION OF THE DRAWINGS

The present invention will now be illustrated in greater detail by means of an embodiment with reference to FIGS. 1 and 2 below reported.

FIG. 1 is a sectional view with respect to plane (A) of FIG. 2, of a photovoltaic device or solar device.

FIG. 2 is a three-dimensional view of the photovoltaic device or solar device of FIG. 1.

FIG. 3 is a graph illustrating the external quantum efficciency of a solar cell.

### DETAILED DESCRIPTION

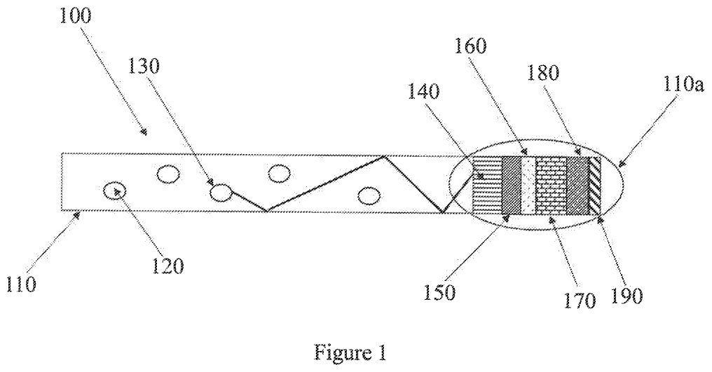

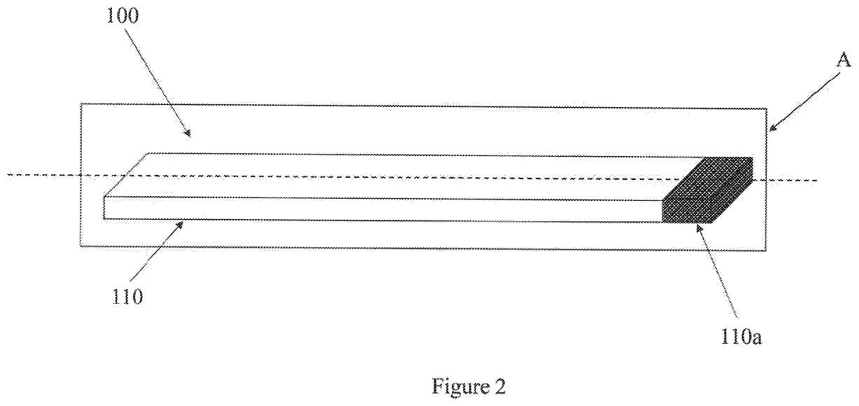

In particular, FIG. 1 represents a sectional view with respect to plane (A) of FIG. 2, of a photovoltaic device (or solar device) (100) comprising: a luminescent solar concentrator (LSC) (110) including at least one photoluminescent compound (120) and a perovskite-based photovoltaic cell (or solar cell) (110a) comprising the following layers: a substrate of glass (140) coated with a layer of transparent and conductive oxide (TCO) (anode) (150); an electron transporter layer (Electron Transport Material—ETO) (160); a layer of perovskite (170); optionally, a scaffold of mesoporous titanium dioxide (TiO₂) (not shown in FIG. 1) positioned between said electron transporter layer (Electron Transport Material—ETO) and said perovskite layer (170); a layer based on a hole transport material (Hole Transport Material—HTM) (180), a metallic contact know as a “back contact” (cathode) (190); optionally, a suitable optical gel (not shown in FIG. 1) positioned between said substrate layer of glass (140) and said luminescent solar concentrator (LSC) (110). In said FIG. 1, an incident photon (130) having a first wavelength enters the luminescent solar concentrator (LSC) (110) and is absorbed by the photoluminescent compound (120) and emitted at a second wavelength different from the first. The incident photons are internally reflected and refracted within the luminescent solar concentrator (LSC) until they reach the photovoltaic cell (or solar cell) (110a) and are converted into electrical energy.

FIG. 2 shows a three-dimensional view of a photovoltaic device (or solar device) (100) comprising a luminescent solar concentrator (LSC) (110) and a perovskite-based photovoltaic cell (or solar cell) (110a).

For the purpose of improving understanding of the present invention and putting it into practice, in what follows we present a number of illustrative and non-limiting examples thereof.

For greater simplicity, in the examples which follow the terms “solar cell” and “solar device” are used, which should be understood as having the same meaning as “photovoltaic cell” and “photovoltaic device”.

### Example 1

### Preparation of Plate 1 (Casting) (LSC1)

In a 4-litre flask were heated, with magnetic stirring, 2500 ml of methyl methacrylate (MMA) (Sigma-Aldrich), previously distilled in order to remove any inhibitors of polymerisation, bringing the temperature to 80° C., in 2 hours. The following were then added: 250 mg 2,2′-azo-bis[2-methylpropionamidine]dihydrochloride (AIBN) (initiator) dissolved in 250 ml of methyl methacrylate (MMA) (Sigma-Aldrich), previously distilled: the temperature of the mixture obtained falls by approximately 3° C.-4° C. Said mixture was heated, bringing the temperature to 94° C. in 1 hour: all this was left at said temperature for 2 minutes and then cooled in an ice bath, obtaining a pre-polymer syrup which, if not used immediately, may be stored for a few weeks in a refrigerator.

A mould was then prepared, assembled with two glass plates of dimensions 100×400×6 mm, separated by a seal in polyvinyl chloride (PVC) of larger diameter equal to 6 mm, held together with metal clamps.

Into a 4-litre glass flask were then added 2 litres of pre-polymer syrup obtained as described above, 120 mg of lauroyl peroxide (Sigma-Aldrich) dissolved in 1 litre of methyl methacrylate (MMA) (Sigma-Aldrich), previously distilled, a quantity of 5,6-diphenoxy-4,7-bis[5-(2,6-dimethylphenyl)-2-thienyl]benzo[c]1,2,5-thiadiazole (MPDTBOP) equal to 200 ppm, 5000 ppm Tinuvin® P (Basf) and 5000 ppm Tinuvin® 770 (Basf): the mixture obtained was maintained with magnetic stirring and under vacuum (10 mm Hg), for 45 minutes, at ambient temperature (25° C.), obtaining a degassed solution. The solution thus obtained was poured into the mould prepared as described above, which, after closing the seal aperture, was immersed in a bath of water at 55° C., for 48 hours. The mould was then placed in an oven at 95° C., for 24 hours (curing step), then removed from the oven and allowed to cool at ambient temperature (25° C.). The metal clamps and the seal were then removed, and the glass plates were separated by isolating plate 1 (LSC1) (the plate was cut to dimensions 75×300×6 mm).

### Example 2

### Preparation of Plate 2 (Casting) (LSC2)

Plate 2 (LSC2) was prepared by working as reported in Example 1, apart from the fact that instead of 5,6-diphenoxy-4,7-bis[5-(2,6-dimethylphenyl)-2-thienyl]benzo[c]1,2,5-thiadiazole (MPDTBOP), 5,6-diphenoxy-4,7-bis[5-(2,5-dimethylphenyl)-2-thienyl]benzo[c]1,2,5-thiadiazole (PPDTBOP) was used in a quantity equal to 200 ppm, obtaining plate 2 (LSC2) (dimensions 75×300×6 mm).

### Example 3

### Preparation of Plate 3 (Casting) (LSC3)

Plate 3 (LSC3) was prepared by working as reported in Example 1, apart from the fact that instead of 5,6-diphenoxy-4,7-bis[5-(2,6-dimethylphenyl)-2-thienyl]benzo[c]1,2,5-thiadiazole (MPDTBOP), N,N′-bis(2′,6′-di-iso-propylphenyl)(1,6,7,12-tetraphenoxy)(3,4,9,10-perilene diimide (Lumogen® F Red 305—Basf) was used in a quantity equal to 160 ppm, obtaining plate 3 (LSC3) (dimensions 75×300×6 mm).

### Example 4

### Preparation of Perovskite-Based Solar Cell

A perovskite-based solar cell was prepared by following, with a few modifications, the procedure described by Li G. et al., in Advanced Energy Materials (2015), 1401775, reported above.

To this end, a perovskite-based solar cell was prepared on a substrate of glass coated with FTO [tin oxide doped with fluorine (SnO₂:F)—(Fluorinated Tin Oxide) (Hartford Glass), previously subjected to a cleaning procedure consisting of cleaning by hand, rubbing with a lint-free cloth soaked in a detergent diluted with distilled water. The substrate was then rinsed with distilled water. The substrate was then deep-cleaned using the following methods in sequence: ultrasound baths in (i) distilled water plus detergent (followed by drying by hand with a lint-free cloth; (ii) distilled water [followed by drying by hand with a lint-free cloth; (iii) acetone (Aldrich) e (iv) iso-propanol (Aldrich) in sequence. In particular, the substrate was placed in a beaker containing the solvent, placed in an ultrasound bath, maintained at 40° C., for a treatment of 10 minutes. After treatments (iii) and (iv), the substrate was dried in a stream of compressed nitrogen.

The glass/FTO was then further cleaned by treating in an ozone device (UV Ozone Cleaning System EXPO3—Astel), immediately before proceeding to the next step.

The thus-treated substrate was ready for deposition of the electron transporter layer (Electron Transport Material—ETO). To this end, a layer of compacted titanium dioxide (TiO₂) was deposited by means of reactive sputtering in a direct current (DC), using titanium dioxide (TiO₂) as the target, in the presence of argon (Ar) (20 sccm) and of oxygen (O₂) (4 sccm) on the substrate. The thickness of the layer of titanium dioxide (TiO₂) was equal to 115 nm.

On top of the layer of titanium dioxide (TiO₂) obtained, a layer of mesoporous titanium dioxide (TiO₂) was deposited by working as follows. To this end, a solution of a mesoporous titanium dioxide (TiO₂) paste (Dyesol 18NRT—Aldrich) (2 g) in ethanol (Aldrich) (6 g) and terpineol (2 g) (Aldrich) was prepared: said solution was deposited by means of spin coating, working at a rotation speed of 2000 rpm (acceleration equal to 1000 rpm/s), for 45 seconds. The thickness of the layer of mesoporous titanium dioxide (TiO₂) was equal to 600 nm. At the end of deposition, all this was subjected to annealing at 500° C. for 2 hours and then again subjected to cleaning by treating in an ozone device (UV Ozone Cleaning System EXPO3—Astel), immediately before proceeding to the next step.

On top of the layer of mesoporous titanium dioxide (TiO₂) thus obtained, the layer of perovskite, i.e. the layer of methyl ammonium lead iodide (CH₃NH₃PbI₃) was deposited by working as follows: i) the lead iodide (PbI₂) (purity 99%—Aldrich) was dissolved in N,N-dimethyl formamide (purity 99.8%—Aldrich) by working with stirring, at a temperature of 75° C., for 30 minutes, obtaining a solution at a concentration of lead iodide (PbI₂) equal to 462 mg/ml, said solution was deposited on said mesoporous layer of titanium dioxide (TiO₂) by means of spin coating, working at a rotation speed of 6000 rpm (acceleration equal to 1000 rpm/s), for 90 seconds and all this was dried at 100° C., for 15 minutes; ii) after cooling at ambient temperature, all this was subjected to dip coating, for 5 minutes, in a solution of methyl ammonium iodide (MAI) (CH₃NH₃I) (purity 98%—Aldrich) in isopropanol (Aldrich) (concentration MAI equal to 10 mg/ml); iii) spin coating of a solution of methyl ammonium iodide (MAI) (CH₃NH₃I) (purity 98%—Aldrich) in isopropanol (Aldrich) (concentration MAI equal to 5 mg/ml), working at a rotation speed of 6000 rpm (acceleration equal to 1000 rpm/s), for 30 seconds (solar cells in what follows indicated as Type A). Regarding the solar cells hereinafter indicated as Type B, the solution of methyl ammonium iodide (MAI) (CH₃NH₃I) (purity 98%—Aldrich) used in step ii) and in step iii) were obtained using said methyl ammonium iodide (MAI) (CH₃NH₃I) after crystallization from heptane before dissolution in isopropanol (concentration of MAI equal to 10 mg/ml). At the end of deposition, all this was subjected to desiccation at 100° C. for 30 minutes and then cooled to ambient temperature (25° C.). The thickness of the layer of perovskite was equal to 300 nm.

On top of the layer of perovskite obtained, a layer based on a hole transport material (HTM) was deposited. To this end, 72.3 mg spiro-MeOTAD [2,2′,7,7′-tetrakis(N,N-di-4-methoxyphenylamine)-9,9′-spirobifluorene] (Aldrich) was dissolved in 1 ml chlorobenzene (purity 99.8%—Aldrich) and then 28.8 μl of 4-tert-butylpyridine (purity 96%—Aldrich) and 17.5 μl of a stock solution at a concentration equal to 520 mg/ml of lithio-bis(trifluoromethylsulfonyl)imide (purity 98%—Alfa Aesar) in acetonitrile (purity 99.8%—Aldrich): the solution thus obtained was deposited, by means of spin coating, working at a rotation speed of 2000 rpm (acceleration equal to 500 rpm/s), for 45 seconds. The thickness of the layer based on hole transport material (HTM) was equal to 150 nm.

On top of said layer based on a hole transport material (HTM) the back contact (cathode) of gold (Au), having a thickness equal to 100 nm, was deposited by evaporation in a vacuum, suitably masking the area of the device in such a way as to obtain an active area equal to 1.28 cm².

Deposition of the cathode was performed in a standard vacuum evaporation chamber containing the substrate and an evaporation container equipped with a heating resistor containing 10 shots of gold (Au) (diameter 1 mm-3 mm) (Aldrich). The evaporation process was conducted in a vacuum, at a pressure of approximately 1×10⁻⁶ bar. The gold (Au), after evaporation, was condensed in the non-masked parts of the device.

The thicknesses were measured by scanning electron microscopy using a Jeol 7600f scanning electron microscope (SEM) fitted with a field emission electron beam, working with acceleration voltage ranging from 1 kV to 5 kV, and utilising the signal originating from secondary electrons.

### Example 5

### Preparation of the Solar Device

On one side of plate 1 (LSC1), obtained as described in Example 1, a perovskite-based solar cell of Type A (PSC—Type A), obtained as described in Example 4, was placed.

To this end a support was produced with a 3D printer, that was capable of maintaining the Type A perovskite-based solar cell (PSC—Type A) close and aligned along the short side of said plate 1 (LSC1), obtaining the solar device (PSC device—Type A).

Then, at the end of electrical characterisation of the solar device (PSC—Type A), the perovskite-based solar cell (PSC—Type A) was substituted with the Type B perovskite-based solar cell (PSC—Type B) obtained as described in Example 4, obtaining the solar device (PSC device—Type B).

For purposes of comparison, at the end of electrical characterisation of the solar device (PSC—Type B), the Type B perovskite-based solar cell (PSC—Type B) was substituted with a silicon solar cell (Si cell) KXOB22-12×1 from IXYS, of dimension 22×6 mm and surface area equal to 1.22 cm², obtaining the solar device (Si Cell Device).

The electrical characterisation of the above-mentioned solar devices, i.e. (PSC Device—Type A), (PSC Device—Type B) and (Si Cell Device), was carried out at ambient temperature (25° C.). The current-voltage (I-V) curves were acquired with a Keithley® 2601A sourcemeter connected to a personal computer to collect the data. The photocurrent was measured by exposing the device to the light of an ABET SUN® 2000-4 solar simulator, positioned at a distance of 10 mm from said plate 1 (LSC 1), capable of providing an irradiation of AM 1.5G, using an illumination spot equal to 100 mm×100 mm: in Table 1, the characteristic parameters are given as mean values.

Table 1 also shows the expected electrical power density (□_{expected}) of the solar devices mentioned above, calculated according to the following equation:

(□_{expected})=(□Si)×EC_{PSC}

wherein:
(□Si) is the electrical power density (mWcm⁻²) of the solar device comprising the silicon solar cell (Si Cell) and the luminescent solar concentrator (LSC) (Si Cell Device);
EC_{PSC} is the photoelectric conversion efficiency of the solar device comprising the perovskite-based solar cell and the luminescent solar concentrator (LSC) (i.e. PSC Device—Type A and PSC Device—Type B).

For the purpose of the present description and of the claims which follow, said photoelectric conversion efficiency (EC_{PSC}), is defined as the ratio between the number of electrons produced in the external circuit within the semiconductor material of the device and the number of photons incident on the perovskite-based solar cell through the luminescent solar concentrator (LSC) and was calculated according to the following equation:

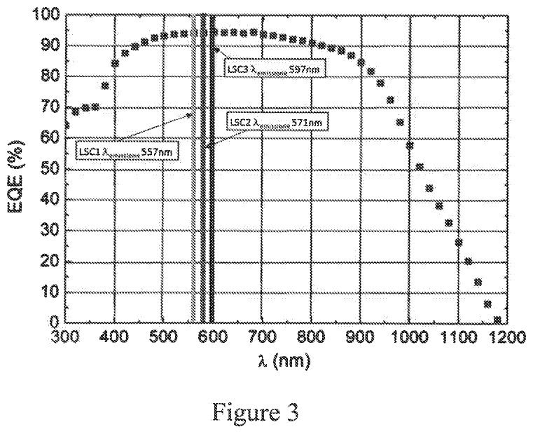

(EC_{PSC})=Jsc_{(PSC)}×6.24×10¹⁵/DFF

wherein:
Jsc_{(PSC)} [short-circuit photocurrent density] measured in (mA/cm²) of the solar device comprising the perovskite-based solar cell and the luminescent solar concentrator (LSC) (i.e. PSC Device—Type A and PSC Device—Type B);
DFF is the photon flow density calculated as stated above. For the purpose of the aforementioned calculation, the external quantum efficiency [EQE (%)] of the silicon solar cell (Si Cell) KXOB22-12×1 from IXYS was used, which as can be seen in FIG. 3, in which the external quantum efficiency [EQE (%)] is shown on the ordinate and the wavelength [□ (nm)] on the abscissa, has a constant value equal to 95% (datum provided by IXYS), within the emission wavelength range (550 nnm-600 nm), of the photoluminescent compounds present in the various luminescent solar concentrators (LSCs), i.e. in plate 1 (LSC1), or in plate 2 (LSC2), or in plate 3 (LSC3): this allows the solar device comprising the silicon solar cell (Si Cell) and the luminescent solar concentrator (LSC) (Si cell Device) to be used for the photon count, i.e. for the photon flow density, which indicates how many photons per second per square centimetre are transported by the above-mentioned luminescent solar concentrators (LSC).

The photon flow density (DFF) was therefore calculated according to the following equation:

(DFF)=Jsc×6.24×10¹⁵/EQE_{Si}

wherein:
Jsc [short-circuit photocurrent density] measured in (mA/cm²) of the solar device comprising the silicon solar cell (Si Cell) and the luminescent solar concentrator (LSC) (Si Cell Device);
EQE_{Si} is the external quantum efficiency (%) of the silicon solar cell (Si Cell) KXOB22-12×1 from IXYS, which value, as stated above, is equal to 95% (see FIG. 3).

### Example 6

### Preparation of the Solar Device

On one side of plate 2 (LSC2), obtained as described in Example 2, a perovskite-based solar cell of Type A (PSC—Type A), obtained as described in Example 4, was placed.

To this end a support was produced with a 3D printer, that was capable of maintaining the Type A perovskite-based solar cell (PSC—Type A) close and aligned along the short side of said plate 2 (LSC2), obtaining the solar device (PSC device—Type A).

Then, at the end of electrical characterisation of the solar device (PSC—Type A), the perovskite-based solar cell (PSC—Type A) was substituted with the Type B perovskite-based solar cell (PSC—Type B) obtained as described in Example 4, obtaining the solar device (PSC device—Type B).

For purposes of comparison, at the end of electrical characterisation of the solar device (PSC—Type B), the Type B perovskite-based solar cell (PSC—Type B) was substituted with the silicon cell (Si cell) mentioned above, obtaining the solar device (Si Cell Device).

The electrical characterisation of the solar devices obtained was carried out as described above: in Table 1, the characteristic parameters are given as mean values.

### Example 7

### Preparation of the Solar Device

On one side of plate 3 (LSC3) obtained as described in Example 3, a perovskite-based solar cell of Type A (PSC—Type A), obtained as described in Example 4, was placed.

To this end a support was produced with a 3D printer, that was capable of maintaining the Type A perovskite-based solar cell (PSC—Type A) close and aligned along the short side of said plate 3 (LSC3), obtaining the solar device (PSC device—Type A).

Then, at the end of electrical characterisation of the solar device (PSC—Type A), the Type A perovskite-based solar cell (PSC—Type A) was substituted with the Type B perovskite-based solar cell (PSC—Type B) obtained as described in Example 4, obtaining the solar device (PSC device Type B).

For purposes of comparison, at the end of electrical characterisation of the solar device (PSC—Type B), the Type B perovskite-based solar cell (PSC—Type B) was substituted with the silicon cell (Si cell) mentioned above, obtaining the solar device (Si Cell Device).

The electrical characterisation of the solar devices obtained was carried out as described above: in Table 1, the characteristic parameters are given as mean values.

### Example 8

### Preparation of the Solar Device

On one side of plate 3 (LSC3) obtained as described in Example 3, a perovskite-based solar cell of Type A (PSC—Type A), obtained as described in Example 4, was placed using the optical gel Norland Index Matching Liquid 150 (product No. 9006 Norland).

To this end a support was produced with a 3D printer, that was capable of maintaining the Type A perovskite-based solar cell (PSC—Type A) close and aligned along the short side of said plate 3 (LSC3), obtaining the solar device (PSC device—Type A).

For purposes of comparison, at the end of electrical characterisation of the solar device (PSC—Type A), the Type A perovskite-based solar cell (PSC—Type A) was substituted with the silicon cell (Si cell) mentioned above, obtaining the solar device (Si Cell Device).

The electrical characterisation of the solar devices obtained was carried out as described above: in Table 1, the characteristic parameters are given as mean values.

TABLE 1

| | Si Cell Device | | | | | | | | | | | | |
|---|---|---|---|---|---|---|---|---|---|---|---|---|---|
| EX- | | DFF⁽²⁾ | | PSC Device-Type A | | | | | PSC Device-Type B | | | | |
| AM- | Jsc⁽¹⁾ | (10¹⁵s⁻¹ | ^{└(3)} | Jsc⁽¹⁾ | | ^{└}_{expected}⁽⁵⁾ | ^{└(3)} | ^{└}/ | Jsc⁽¹⁾ | | ^{└}_{expected}⁽⁵⁾ | ^{└(3)} | ^{└}/ |
| PLE | (mAcm⁻²) | cm⁻²) | (mWcm⁻²) | (mAcm⁻²) | ECPsc⁽⁴⁾ | (mWcm⁻²) | (mWcm⁻²) | ^{└}_{expected} | (mAcm⁻²) | EC_{PSC}⁽⁴⁾ | (mWcm⁻²) | (mWcm⁻²) | ^{└}_{expected} |
| 5 | 8.7 | 57.4 | 3.4 | 5.0 | 0.54 | 1.8 | 2.8 | 1.6 | 6.2 | 0.67 | 2.3 | 2.9 | 1.3 |
| 6 | 10.3 | 67.8 | 4.1 | 5.4 | 0.50 | 2.0 | 3.1 | 1.6 | 6.1 | 0.56 | 2.3 | 3.2 | 1.4 |
| 7 | 10.8 | 71.2 | 5.0 | 6.2 | 0.54 | 2.7 | 3.6 | 1.3 | 6.7 | 0.59 | 2.9 | 3.7 | 1.3 |
| 8 | 23.1 | 151.7 | 9.9 | 12.8 | 0.53 | 5.2 | 6.5 | 1.3 | — | — | — | — | — |

⁽¹⁾short-circuit photocurrent density;
⁽²⁾photon flow density;
⁽³⁾electrical power density;
⁽⁴⁾photoelectric conversion efficiency;
⁽⁵⁾electrical power density expected.

From the data given in Table 1 it can be seen that the photovoltaic device (or solar device) object of the present invention exhibits a ratio between the electrical power density (└) generated and the electrical power density expected (└_{expected}) defined as stated above, greater than 1 and, consequently, a higher generated electrical power density (└) with respect to that expected.

1. A photovoltaic device or solar device comprising:
at least one luminescent solar concentrator (LSC) having an upper surface, a lower surface and one or more external sides;
at least one perovskite-based photovoltaic cell or solar cell, the photovoltaic cell or solar cell positioned outside of at least one of the external sides of the luminescent solar concentrator (LSC), wherein the perovskite is selected from organometal trihalides.

2. The photovoltaic device or solar device according to claim 1, wherein the luminescent solar concentrator (LSC) has an upper surface configured to receive photons, a lower surface configured to receive photons, wherein the upper surface is positioned closer to a photon source with respect to the lower surface, and four external sides that extend from the upper surface to the lower surface.

3. The photovoltaic device (or solar device) according to claim 1, wherein the luminescent solar concentrator (LSC) is a plate comprising a matrix in transparent material and at least one photoluminescent compound.

4. The photovoltaic device or solar device according to claim 3, wherein the transparent material is selected from the group consisting of: polymethyl methacrylate (PMMA), polycarbonate (PC), polyisobutyl methacrylate, polyethyl methacrylate, polyallyl diglycol carbonate, polymethacrylimide, polycarbonate ether, polyethylene terephthalate, polyvinyl butyral, ethylene-vinylacetate copolymers, ethylene-tetrafluoroethylene copolymers, polyimide, polyurethane, styrene-acrylonitrile copolymers, styrene-butadiene copolymers, polystyrene, methyl-methacrylate styrene copolymers, polyethersulfone, polysulfone, cellulose triacetate, transparent and impact-resistant crosslinked acrylic compositions, transparent glass and mixtures thereof;
wherein the transparent material has a refractive index ranging from 1.30 to 1.70;
wherein the transparent glass is selected from the group consisting of silica, quartz, alumina, titanium dioxide, and mixtures thereof; and
wherein the transparent and impact-resistant crosslinked acrylic compositions consist of a fragile matrix (I) having a glass transition temperature (T_{g}) above 0° C. and elastomeric domains having dimensions smaller than 100 nm that consist of macromolecular sequences (II) having a flexible nature with a glass transition temperature (T_{g}) below 0° C. (PPMA-IR), or mixtures thereof.

5. The photovoltaic device or solar device according to claim 3, wherein the photoluminescent compound is selected from perylene compounds; acene compounds; benzothiadiazole compounds; compounds comprising a benzoheterodiazole group and at least one benzodithiophene group; disubstituted naphthathiadiazole compounds; benzoheterodiazole compounds disubstituted with benzodithiophene groups; disubstituted benzoheterodiazole compounds; disubstituted diaryloxybenzoheterodiazole compounds; and mixtures thereof.

6. The photovoltaic device or solar device according to claim 3, wherein the photoluminescent compound is present in the transparent matrix in a quantity ranging from 0.1 g per unit of surface area to 3 g per unit of surface area, wherein the unit of surface area being referred to the surface area of the matrix of transparent material expressed in m².

7. The photovoltaic device or solar device according to claim 3, wherein the photoluminescent compound is selected from quantum dots (QDs) that can be composed of different elements selected from the elements belonging to groups 12-16, 13-15, 14-16, of a Periodic Table of the Elements or mixtures thereof.

8. The photovoltaic device or solar device, according to claim 7, wherein the photoluminescent compound selected from quantum dots (QDs) is present in the transparent matrix in a quantity ranging from 0.05 g per unit of surface area to 100 g per unit of surface area, wherein the unit of surface area being referred to is the surface area of the matrix of transparent material expressed in m².

9. The photovoltaic device or solar device according to claim 1, wherein the luminescent solar concentrator (LSC) is a plate having a thickness ranging from 0.1 mm to 50 mm.

10. The photovoltaic device or solar device according to claim 1, wherein the perovskite is selected from organometal trihalides having a general formula ABX₃, wherein:
A represents an organic cation such as methylammonium (CH₃NH₃⁺), formamidinium [CH(NH₂)₂⁺], n-butylammonium (C₄H₁₂N⁺), tetra-butylammonium (C₁₆H₃₆N⁺);
B represents a metallic cation such as lead (Pb²⁺), tin (Sn²⁺);
X represents a halogen ion such as iodine (I⁻), chlorine (Cl⁻), bromine (Br⁻).

11. The photovoltaic device or solar device according to claim 1, wherein the perovskite is selected from: methyl ammonium lead iodide (CH₃NH₃PbI₃), methyl ammonium lead bromide (CH₃NH₃PbBr₃), methyl ammonium lead chloride (CH₃NH₃PbCl₃), methyl ammonium lead iodide bromide (CH₃NH₃PbIₓBr₃₋ₓ), methyl ammonium lead iodide chloride (CH₃NH₃PbIₓCl₃₋ₓ), formamidinium lead iodide [CH(NH₂)₂PbI₃], formamidinium lead bromide [CH(NH₂)₂PbBr₃], formamidinium lead chloride [CH(NH₂)₂PbCl₃], formamidinium lead iodide bromide [CH(NH₂)₂PbIₓBr₃₋ₓ], formamidinium lead iodide chloride [CH(NH₂)₂PbIₓCl₃₋ₓ], n-butyl ammonium lead iodide (C₄H₁₂NPbI₃), tetra-butyl ammonium lead iodide (C₁₆H₃₆NPbI₃), n-butyl ammonium lead bromide (C₄H₁₂NPbBr₃), tetra-butyl ammonium lead bromide (C₁₆H₃₆NPbBr₃), methyl ammonium tin iodide (CH₃NH₃SnI₃), methyl ammonium tin bromide (CH₃NH₃SnBr₃), methyl ammonium tin iodide bromide (CH₃NH₃SnIₓBr₃₋ₓ), formamidinium tin iodide [CH(NH₂)₂SnI₃], formamidinium tin iodide bromide [CH(NH₂)₂SnIₓBr₃₋ₓ], n-butyl ammonium tin iodide (C₄H₁₂NSnI₃), tetra-butyl ammonium tin iodide (C₁₆H₃₆NSnI₃), n-butyl ammonium tin bromide (C₄H₁₂NSnBr₃), tetra-butyl ammonium tin bromide (C₁₆H₃₆NSnBr₃), methyl ammonium tin iodide (CH₃NH₃SnI₃), or mixtures thereof.

12. The photovoltaic device or solar device according to claim 1, wherein the at least one perovskite-based photovoltaic cell or solar cell is coupled to at least one of the external sides of the luminescent solar concentrator (LSC) with use of a optical gel, wherein the optical gel is selected from the group consisting of transparent silicone oils and fats, and epoxy resins.

13. The photovoltaic device or solar device according to claim 1, wherein the electrical energy generated by the at least one perovskite-based photovoltaic cell or solar cell is transported using a wiring system that is connected to the photovoltaic device or solar device.

14. The photovoltaic device or solar device according to claim 1 wherein the photovoltaic device or solar device is used in applications selected from the group consisting of building integrated photovoltaic (BIPV) systems, photovoltaic windows, greenhouse, photobioreactors, noise barriers, lighting equipment, design, advertising, and automotive industry.

15. The photovoltaic device or solar device according to claim 1, wherein the perovskite is methyl ammonium lead iodide (CH₃NH₃PbI₃).

16. The photovoltaic device or solar device according to claim 3, wherein the photoluminescent compound is selected from the group consisting of perylene compounds such as N,N′-bis(2′,6′-di-iso-propylphenyl)(1,6,7,12-tetraphenoxy)(3,4,9,10-perylene diimide (Lumogen® F Red 305—Basf), 9,10-diphenylanthracene (DPA), 4,7-di(thien-2′-yl)-2,1,3-benzothiadiazole (DTB), 5,6-diphenoxy-4,7-bis(2-thienyl)-2,1,3-benzothiadiazole (DTBOP), 5,6-diphenoxy-4,7-bis[5-(2,6-dimethylphenyl)-2-thienyl]benzo[c]1,2,5-thiadiazole (MPDTBOP), 5,6-diphenoxy-4,7-bis[5-(2,5-dimethylphenyl)-2-thienyl]benzo[c]1,2,5-thiadiazole (PPDTBOP), 4,7-bis[5-(2,6-dimethylphenyl)-2-thienyl]benzo[c]1,2,5-thiadiazole (MPDTB), 4,7-bis[5-(2,6-di-iso-propylphenyl)-2-thienyl]benzo[c]1,2,5-thiadiazole (IPPDTB), 4,7-bis[4,5-(2,6-dimethylphenyl)-2-thienyl]benzo[c]1,2,5-thiadiazole (2MPDTB) 4,7-bis(7′,8′-dibutylbenzo[1′,2′-b′:4′,3′-b″]dithien-5′-yl)-benzo[c] [1,2,5]thiadiazole (F500), 4,9-bis(7′,8′-dibutylbenzo[1′,2′-b′:4′,3′-b″]dithien-5′-yl)-naphtho[2,3-c][1,2,5]thiadiazole (F521), 4,7-bis(5-(thiophen-2-yl)thiophen-2-yl)benzo[c][1,2,5]thiadiazole (QTB), 4,9-bis(thien-2′-yl)-naphtho[2,3-c][1,2,5]thiadiazole (DTN), and mixtures thereof.

17. The photovoltaic device or solar device according to claim 3, wherein the photoluminescent compound is selected from the group consisting of perylene compounds such as 9,10-5,6-diphenoxy-4,7-bis[5-(2,6-dimethylphenyl)-2-thienyl]benzo[c]1,2,5-thiadiazole (MPDTBOP), 5,6-diphenoxy-4,7-bis[5-(2,5-dimethylphenyl)-2-thienyl]benzo[c]1,2,5-thiadiazole (PPDTBOP), N,N′-bis(2′,6′-di-iso-propylphenyl)(1,6,7,12-tetraphenoxy)(3,4,9,10-perylene diimide (Lumogen® F Red 305—Basf), and mixtures thereof.

18. The photovoltaic device or solar device according to claim 3, wherein the photoluminescent compound is present in the transparent matrix in a quantity ranging from 0.2 g per unit of surface area to 2.5 g per unit of surface area, and wherein the unit of surface area being referred to is the surface area of the matrix of transparent material expressed in m².

19. The photovoltaic device or solar device according to claim 3, wherein the photoluminescent compound is selected from quantum dots (QDs) that can be composed of different elements selected the group consisting of lead sulphide (PbS), zinc sulphide (ZnS), cadmium sulphide (CdS, cadmium selenide (CdSe), cadmium telluride (CdTe), silver (Ag), gold (Au), aluminium (Al), and mixtures thereof.

20. The photovoltaic device or solar device according to claim 4, wherein the transparent material is selected from polymethylmethacrylate (PMMA), PMMA-IR, or mixtures thereof.
